(19) United States
(12) Patent Application Publication
(10) Pub. No.: US 2019/0355546 A1
(43) Pub. Date: Nov. 21, 2019

(54) MULTIPLE ELECTRON BEAM IMAGE ACQUISITION APPARATUS AND MULTIPLE ELECTRON BEAM IMAGE ACQUISITION METHOD

(71) Applicant: NuFlare Technology, Inc., Yokohama-shi (JP)

(72) Inventors: Atsushi Ando, Edogawa-ku (JP); Kiyoshi Hattori, Minato-ku (JP)

(73) Assignee: NuFlare Technology, Inc., Yokohama-shi (JP)

(21) Appl. No.: 16/381,052

(22) Filed: Apr. 11, 2019

(30) Foreign Application Priority Data
May 16, 2018 (JP) 2018-094916

(51) Int. Cl. H01J 37/147; H01J 37/141; H01J 37/09; H01J 37/244

(52) U.S. Cl. CPC H01J 37/1471; H01J 37/141; H01J 2237/152; H01J 37/244; H01J 2237/2448; H01J 37/09

(57) ABSTRACT

A multiple electron beam image acquisition apparatus includes an electromagnetic lens to receive multiple electron beams and refract them, a beam selection mechanism, in the magnetic field of the electromagnetic lens, to individually correct the trajectory of each of the multiple electron beams and select a variable desired number of beams from the multiple electron beams, a limiting aperture substrate to block beams which were not selected from the multiple electron beams, a magnification adjustment system to change magnification of the beams selected, depending on the number of beams, being the desired number, selected from the multiple electron beams, an objective lens to focus the beams selected onto the target object surface, a beam separator to separate, from the beams selected, secondary electrons emitted because of the target object surface being irradiated with the beams selected, and a detector to detect the secondary electrons separated by the beam separator.

### CROSS-REFERENCE TO RELATED APPLICATION

This application is based upon and claims the benefit of priority from prior Japanese Patent Application No. 2018-094916 filed on May 16, 2018 in Japan, the entire contents of which are incorporated herein by reference.

### BACKGROUND OF THE INVENTION

### Field of the Invention

Embodiments of the present invention relate to a multiple electron beam image acquisition apparatus, and multiple electron beam image acquisition method. For example, embodiments of the present invention relate to an inspection apparatus for inspecting a pattern by acquiring a secondary electron image of the pattern emitted by irradiation with multiple electron beams.

### Description of Related Art

In recent years, with the advance of high integration and large capacity of LSI (Large Scale Integration or Integrated circuits), the line width (critical dimension) required for circuits of semiconductor elements is becoming increasingly narrower. Since LSI manufacturing requires a tremendous amount of manufacturing cost, it is crucially essential to improve its yield. However, as typified by a 1-gigabit DRAM (Dynamic Random Access Memory), the scale of patterns which configure the LSI now has become on the order of nanometers from submicrons. Also, in recent years, with miniaturization of LSI patterns formed on a semiconductor wafer, dimensions of a pattern defect needed to be detected have become extremely small. Therefore, the pattern inspection apparatus for inspecting defects of ultrafine patterns exposed (transferred) on the semiconductor wafer needs to be highly accurate. Further, one of major factors that decrease the yield of the LSI manufacturing is due to pattern defects on the mask used for exposing (transferring) an ultrafine pattern onto a semiconductor wafer by the photolithography technology. Therefore, the pattern inspection apparatus for inspecting defects on a transfer mask used in manufacturing LSI needs to be highly accurate.

As an inspection method, there is known a method of comparing a measured image captured by imaging a pattern formed on the substrate, such as a semiconductor wafer and a lithography mask, with design data or with another measured image captured by imaging an identical pattern on the substrate. For example, the methods described below are known as pattern inspection, “die-to-die inspection” and “die-to-database inspection”: the “die-to-die inspection” method compares data of measured images captured by imaging identical patterns at different positions on the same substrate; and the “die-to-database inspection” method generates design image data (reference image), based on pattern design data, to be compared with a measured image serving as measured data captured by imaging a pattern. Then, obtained captured images are transmitted as measured data to the comparison circuit. After providing alignment between images, the comparison circuit compares the measured data with the reference data in accordance with an appropriate algorithm, and determines that there is a pattern defect if the compared data are not identical.

As the pattern inspection apparatus described above, in addition to the apparatus which irradiates the inspection substrate with laser beams in order to obtain a transmission image or a reflection image of a pattern formed on the substrate, there has been developed another inspection apparatus which acquires a pattern image by scanning the inspection substrate with electron beams and detecting secondary electrons emitted from the inspection substrate along with the irradiation by the electron beams. Further, as to the inspection apparatus using electron beams, an apparatus which uses multiple beams is also developed. In the multi-beam inspection, there is a case where an image captured with high accuracy needs to be observed after defect detection has been performed at high speed. However, the image having been used for the defect detection has a problem where the resolution is insufficient to highly accurately observe a defect. In contrast, if the resolution is increased, since the beam condition such as a pitch between beams of multiple beams becomes different, it does not accord with the sensing element pitch of the detector, thereby being unable to perform detection. Moreover, if the configuration of the detector is made to match the beam condition in which the resolution has been increased, the throughput decreases, thereby being difficult to perform high-speed defect inspection. Thus, there is a limit to compatibly perform a high-speed defect inspection and a highly accurate observation by the same inspection apparatus.

Here, there is proposed to deflect a plurality of charged particle beams so as to correct chromatic aberration and spherical aberration by using an aberration corrector composed of a lens array, a quadrupole array, and a deflector array in which are disposed a plurality of deflectors having a function of a concave lens for deflecting the charged particle beam to be away from the optical axis (Japanese Patent Application Laid-open (JP-A) No. 2014-229481).

### BRIEF SUMMARY OF THE INVENTION

According to one aspect of the present invention, a multiple electron beam image acquisition apparatus includes an electromagnetic lens configured to receive incidence of multiple electron beams and refract them, abeam selection mechanism disposed in a magnetic field of the electromagnetic lens, and configured to be able to individually correct a trajectory of each beam of the multiple electron beams and select a desired number of beams from the multiple electron beams, where the desired number is variable, a limiting aperture substrate configured to block beams which were not selected from the multiple electron beams, a magnification adjustment optical system configured to change magnification of the beams selected, depending on a number of the beams, being the desired number, selected from the multiple electron beams, an objective lens configured to focus the beams selected onto a surface of a target object, a beam separator configured to separate, from the beams selected, secondary electrons emitted due to that the surface of the target object was irradiated with the beams selected, and a detector configured to detect the secondary electrons separated by the beam separator.

According to another aspect of the present invention, a multiple electron beam image acquisition method includes selecting, as a mode, one of a first mode and a second mode, selecting a desired number of beams, where the desired number is variable depending on the mode selected, by a beam selection mechanism disposed in a magnetic field of an electromagnetic lens for refracting multiple electron beams, and configured to be able to individually correct a trajectory of each beam of the multiple electron beams, blocking beams which were not selected from the multiple electron beams, changing magnification of the beams selected, depending on the mode selected, focusing the beams selected onto a surface of a target object, and acquiring an image of a pattern on the surface of the target object by detecting secondary electrons emitted due to that the surface of the target object was irradiated with the beams selected.

### BRIEF DESCRIPTION OF THE DRAWINGS

FIG. 1 shows a configuration of a pattern inspection apparatus according to a first embodiment;

FIG. 2 is a conceptual diagram showing a configuration of a shaping aperture array substrate according to the first embodiment;

FIG. 3 is a sectional view showing an example of a structure of a trajectory corrector and an arrangement position according to the first embodiment;

FIGS. 4A to 4C are top views showing examples of an electrode substrate of a trajectory corrector according to the first embodiment;

FIGS. 5A and 5B each illustrates a beam size in an inspection mode according to the first embodiment;

FIG. 6 illustrates trajectory correction of an electron beam by a trajectory corrector according to a comparative example of the first embodiment;

FIG. 7 illustrates trajectory correction of an electron beam by a trajectory corrector according to the first embodiment;

FIG. 8 illustrates magnification adjustment in an observation mode according to the first embodiment;

FIG. 9 is a flowchart showing main steps of an inspection method according to the first embodiment;

FIG. 10 shows an example of a plurality of chip regions formed on a semiconductor substrate, according to the first embodiment;

FIG. 11 shows an example of an irradiation region and a measurement pixel of multiple beams according to the first embodiment;

FIG. 12 shows an example of a configuration inside a comparison circuit according to the first embodiment;

FIG. 13 is a top view showing an example of a middle electrode substrate of a trajectory corrector according to a modified example 1 of the first embodiment; and

FIG. 14 is a sectional view showing an example of a trajectory corrector according to a modified example 2 of the first embodiment.

### DETAILED DESCRIPTION OF THE INVENTION

Embodiments below describe an apparatus and method which can compatibly perform a defect inspection and a highly accurate observation by the same apparatus when acquiring an image with multiple electron beams.

Embodiments below describe a multiple electron beam inspection apparatus as an example of a multiple electron beam image acquisition apparatus. The multiple electron beam image acquisition apparatus is not limited to the inspection apparatus, and, for example, may be an apparatus capable of acquiring images by irradiating multiple electron beams.

### First Embodiment

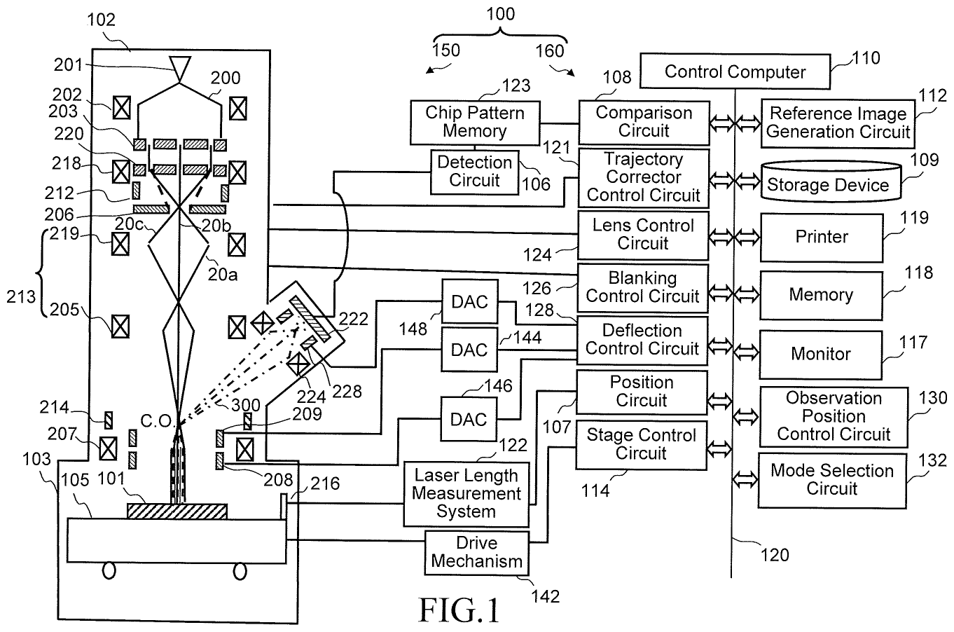

FIG. 1 shows a configuration of a pattern inspection apparatus according to a first embodiment. In FIG. 1, an inspection apparatus 100 for inspecting patterns formed on the substrate is an example of a multiple electron beam inspection apparatus. The inspection apparatus 100 includes an image acquisition mechanism 150 and a control system circuit 160. The image acquisition mechanism 150 includes an electron beam column 102 (also called an electron optical column) (an example of a multi-beam column), an inspection chamber 103, a detection circuit 106, a chip pattern memory 123, a drive mechanism 142, and a laser length measuring system 122. In the electron beam column 102, there are arranged an electron gun 201, an illumination lens 202, a shaping aperture array substrate 203, an electromagnetic lens 218, a trajectory corrector 220, a common blanking deflector 212, a limiting aperture substrate 206, a magnification adjustment optical system 213, an objective lens 207, a main deflector 208, a sub deflector 209, a beam separator 214, a projection lens 224, a deflector 228, and a multi-detector 222. The magnification adjustment optical system 213 is composed of two electromagnetic lenses 219 and 205, for example.

In the inspection chamber 103, there is arranged an XY stage 105 movable at least in the x-y plane. On the XY stage 105, there is placed a substrate 101 (target object) to be inspected. The substrate 101 may be an exposure mask substrate, or a semiconductor substrate such as a silicon wafer. When the substrate 101 is a semiconductor substrate, a plurality of chip patterns (wafer die) are formed on the semiconductor substrate. When the substrate 101 is an exposure mask substrate, a chip pattern is formed on the exposure mask substrate. The chip pattern is composed of aplurality of figure patterns. If a chip pattern formed on the exposure mask substrate is exposed (transferred) onto the semiconductor substrate a plurality of times, a plurality of chip patterns (wafer die) are formed on the semiconductor substrate. The below mainly describes the case where the substrate 101 is a semiconductor substrate. The substrate 101 is placed with its pattern forming surface facing upward, on the XY stage 105, for example. Moreover, on the XY stage 105, there is disposed a mirror 216 which reflects a laser beam for measuring a laser length emitted from the laser length measuring system 122 disposed outside the inspection chamber 103. The multi-detector 222 is connected, at the outside of the electron beam column 102, to the detection circuit 106. The detection circuit 106 is connected to the chip pattern memory 123.

In the control system circuit 160, a control computer 110 which controls the whole of the inspection apparatus 100 is connected, through a bus 120, to a position circuit 107, a comparison circuit 108, a reference image generation circuit 112, a stage control circuit 114, a trajectory corrector control circuit 121, a lens control circuit 124, a blanking control circuit 126, a deflection control circuit 128, an observation position control circuit 130, a mode selection circuit 132, a storage device 109 such as a magnetic disk drive, a monitor 117, a memory 118, and a printer 119. The deflection control circuit 128 is connected to DAC (digital-to-analog conversion) amplifiers 144, 146, and 148. The DAC amplifier 146 is connected to the main deflector 208, and the DAC amplifier 144 is connected to the sub deflector 209. The DAC amplifier 148 is connected to the deflector 228.

The chip pattern memory 123 is connected to the comparison circuit 108. The XY stage 105 is driven by the drive mechanism 142 under the control of the stage control circuit 114. In the drive mechanism 142, the XY stage 105 can be moved by a drive system, such as a three (x-, y-, and θ-) axis motor which moves in the directions of x, y, and θ in the stage coordinate system. For example, a step motor can be used as each of these X, Y, and θ motors (not shown). The XY stage 105 is movable in the horizontal direction and the rotation direction by the motors of the X-axis, Y-axis, and θ-axis. The movement position of the XY stage 105 is measured by the laser length measuring system 122, and supplied (transmitted) to the position circuit 107. Based on the principle of laser interferometry, the laser length measuring system 122 measures the position of the XY stage 105 by receiving a reflected light from the mirror 216. In the stage coordinate system, the X, Y, and θ directions are set with respect to a plane orthogonal to the optical axis of the multiple primary electron beams, for example.

To the electron gun 201, there is connected a high voltage power supply circuit (not shown). The high voltage power supply circuit applies an acceleration voltage between the filament and the extraction electrode (anode) (which are not shown) in the electron gun 201. In addition to applying the acceleration voltage as described above, applying a predetermined voltage to the extraction electrode (Wehnelt) and heating the cathode to a predetermined temperature are performed, and thereby, electrons from the cathode are accelerated to be emitted as an electron beam 200. For example, electromagnetic lenses are used as the illumination lens 202, the objective lens 207, and the projection lens 224, and all of them along with the electromagnetic lenses 218, 219, and 205 are controlled by the lens control circuit 124. The beam separator 214 is also controlled by the lens control circuit 124. The common blanking deflector 212 is composed of at least two e2lectrodes (or “at least two poles”), and controlled by the blanking control circuit 126. The main deflector 208 is composed of at least four electrodes (or “at least four poles”), and controlled by the deflection control circuit 128 through the DAC amplifier 146 disposed for each electrode. The sub deflector 209 is composed of at least four electrodes (or “at least four poles”), and controlled by the deflection control circuit 128 through the DAC amplifier 144 disposed for each electrode. Moreover, the trajectory corrector 220 is controlled by the trajectory corrector control circuit 121. The deflector 228 is composed of at least four electrodes (or “at least four poles”), and controlled by the deflection control circuit 128 through the DAC amplifier 148 with respect to each electrode.

FIG. 1 shows configuration elements necessary for describing the first embodiment. It should be understood that other configuration elements generally necessary for the inspection apparatus 100 may also be included therein.

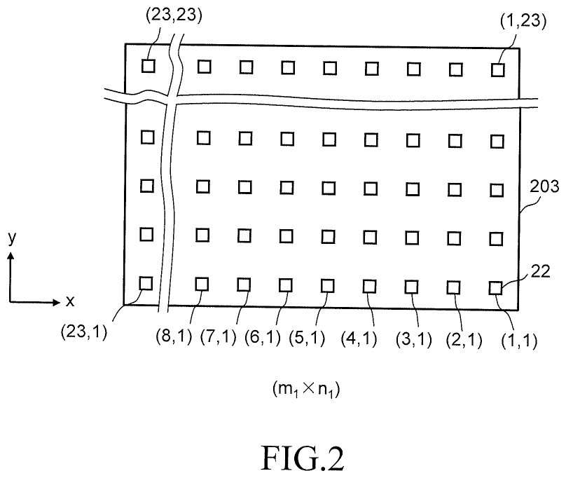

FIG. 2 is a conceptual diagram showing a configuration of a shaping aperture array substrate according to the first embodiment. As shown in FIG. 2, holes (openings) 22 of m₁ columns wide (width in the x direction) and n₁ rows long (length in the y direction) are two-dimensionally formed at a predetermined arrangement pitch in the shaping aperture array substrate 203, where m₁ and n₁ are integers of 2 or greater. In the case of FIG. 2, holes 22 of 23 (columns of holes arrayed in the x direction)×23 (rows of holes arrayed in the y direction) are formed. Each of the holes 22 is a rectangle (including a square) having the same dimension, shape, and size. Alternatively, each of the holes 22 maybe a circle with the same outer diameter. The multiple beams 20 are formed by letting portions of the electron beam 200 individually pass through a corresponding one of a plurality of holes 22. With respect to the arrangement of the holes 22, although here is shown the case where the holes 22 of two or more rows and columns are arranged in both the x and y directions, the arrangement is not limited thereto. For example, it is also acceptable that a plurality of holes 22 are arranged in only one row (in the x direction) or in only one column (in the y direction). That is, in the case of only one row, a plurality of holes 22 are arranged in the x direction as a plurality of columns, and in the case of only one column, a plurality of holes 22 are arranged in the y direction as a plurality of rows. The method of arranging the holes 22 is not limited to the case of FIG. 2 where holes are arranged in a grid form in the width and length directions. For example, with respect to the kth and the (k+1)th rows which are arrayed (accumulated) in the length direction (in the y direction) and each of which is in the x direction, each hole in the kth row and each hole in the (k+1)th row may be mutually displaced in the width direction (in the x direction) by a dimension “a”. Similarly, with respect to the (k+1)th and the (k+2)th rows which are arrayed (accumulated) in the length direction (in the y direction) and each of which is in the x direction, each hole in the (k+1)th row and each hole in the (k+2)th row may be mutually displaced in the width direction (in the x direction) by a dimension “b”.

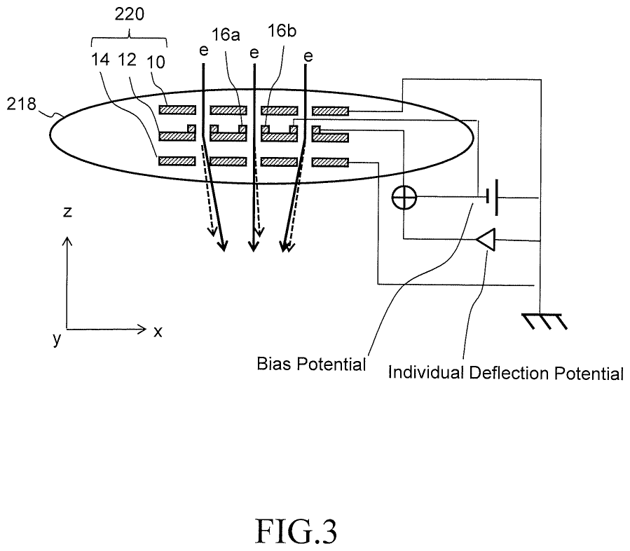

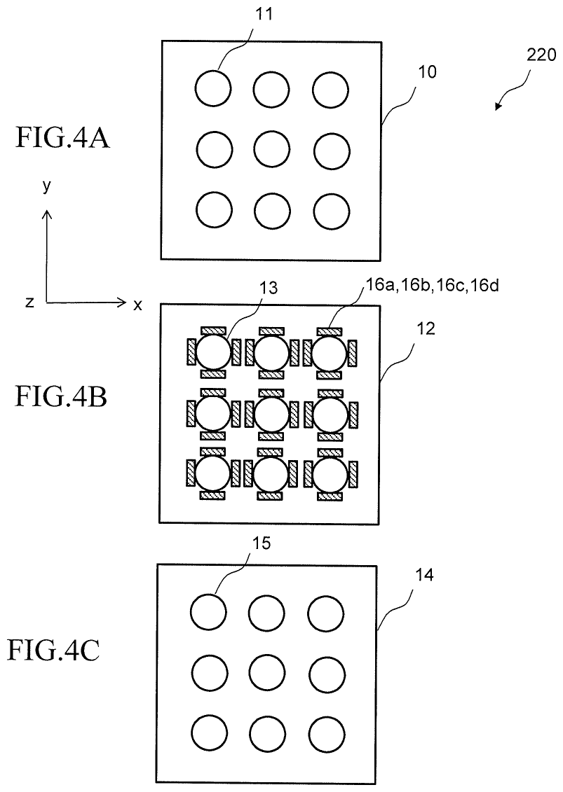

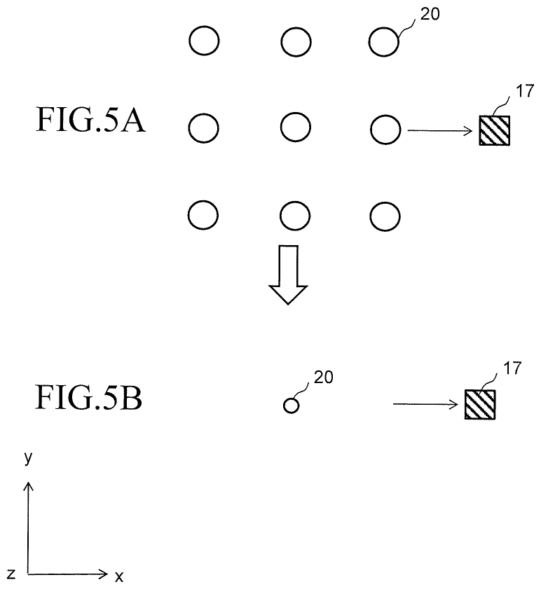

FIG. 3 is a sectional view showing an example of a structure of a trajectory corrector and an arrangement position according to the first embodiment. FIGS. 4A to 4C are top views showing examples of an electrode substrate of a trajectory corrector according to the first embodiment. In FIG. 3 and FIGS. 4A to 4C, the trajectory corrector 220 is disposed in the magnetic field of the electromagnetic lens 218. The trajectory corrector 220 is configured by three or more electrode substrates arranged with predetermined mutual spaces. FIG. 3 and FIGS. 4A to 4C show the trajectory corrector 220 configured by three electrode substrates 10, 12, and 14 (a plurality of substrates), for example. In the cases of FIG. 3 and FIGS. 4A to 4C, 3×3 multiple beams 20 are used. A plurality of passage holes through which the multiple beams 20 pass are formed in the electrode substrates 10, 12, and 14. As shown in FIG. 4A, a plurality of passage holes 11 (openings) are formed at the positions, through each of which a corresponding one of the multiple beams 20(e) passes, of the upper electrode substrate 10. Similarly, as shown in FIG. 4B, a plurality of passage holes 13 (openings) are formed at the positions, through each of which a corresponding one of the multiple beams 20(e) passes, of the middle electrode substrate 12. Similarly, as shown in FIG. 4C, a plurality of passage holes 15 (openings) are formed at the positions, through each of which a corresponding one of the multiple beams 20(e) passes, of the lower electrode substrate 14. The upper and lower electrode substrates 10 and 14 are formed from conductive material. Alternatively, a film of conductive material may be applied on the surface of insulating material. A ground potential (GND) is applied to both the upper and lower electrode substrates 10 and 14 by the trajectory corrector control circuit 121.

On the other hand, on the middle electrode substrate 12 located between the upper and lower electrode substrates 10 and 14, there are disposed a plurality of electrode sets each composed of two or more electrodes 16 such that they sandwich/surround a corresponding one of the multiple beams 20 passing through the passage holes 13. The example of FIG. 4B shows the case where a plurality of electrode sets each composed of four electrodes 16a, 16b, 16c, and 16d are arranged, for each passage hole 13, surrounding a corresponding one of the multiple beams 20 passing through the passage holes 13. The electrodes 16a, 16b, 16c, and 16d are formed from conductive material. The electrode substrate 12 is formed, for example, from silicon material. A wiring layer is formed on the electrode substrate 12 by using, for example, MEMS (Micro Electro Mechanical Systems) technology. Then, the electrodes 16a, 16b, 16c, and 16d are individually formed on corresponding wiring in the wiring layer on the electrode substrate 12 such that they do not electrically conduct with each other. For example, a wiring layer and an insulating layer are formed on the silicon substrate, and then, each of the electrodes 16a, 16b, 16c, and 16d is disposed on the insulating layer and connected to corresponding wiring. It is configured such that the same bias potential (first trajectory correction potential) of each beam can be independently applied to each of the four electrodes 16a, 16b, 16c, and 16d in the electrode set for the passage hole 13. A negative potential is applied as the bias potential. Further, it is configured such that, in each electrode set, in order to generate a potential difference (voltage) between two opposite electrodes 16a and 16b (or/and 16c and 16d) across the passage hole 13, an individual deflection potential (second trajectory correction potential) can be applied to one of the two opposite electrodes, if needed. Therefore, in the trajectory corrector control circuit 121, there are arranged, for each passage hole 13 (for each beam), one power supply circuit for applying a bias potential and at least two power supply circuits for applying a deflection potential. If when the electrode set for each passage hole 13 is composed of eight electrodes, one power supply circuit for applying a bias potential and at least four power supply circuits for applying a deflection potential are arranged for each passage hole 13.

Using the electron multiple beams 20, the image acquisition mechanism 150 acquires an image of a figure pattern, to be inspected, from the substrate 101 on which figure patterns are formed. Hereinafter, operations of the image acquisition mechanism 150 in the inspection apparatus 100 will be described. First, operations in an inspection mode are described.

The electron beam 200 emitted from the electron gun 201 (emission source) almost perpendicularly (e.g., vertically) illuminates the whole of the shaping aperture array substrate 203 by the illumination lens 202. As shown in FIG. 2, a plurality of rectangular (including square) holes 22 (openings) are formed in the shaping aperture array substrate 203. The region including all the plurality of holes 22 is irradiated by the electron beam 200. For example, a plurality of rectangular electron beams (multiple beams) 20a to 20c (solid lines in FIG. 1) (multiple primary electron beams) are formed by letting portions of the electron beam 200, which irradiate the positions of a plurality of holes 22, individually pass through a corresponding one of the plurality of holes 22 in the shaping aperture array substrate 203.

The formed multiple beams 20a to 20c are refracted toward the hole in the center of the limiting aperture substrate 206 by the electromagnetic lens 218. In other words, when receiving the incident multiple beams 20, the electromagnetic lens 218 refracts them. Here, the electromagnetic lens 218 refracts the multiple beams 20a to 20c such that the focus position of each beam is located at the position of the hole in the center of the limiting aperture substrate 206. At this stage, when all of the multiple beams 20a to 20c are collectively deflected by the common blanking deflector 212, they are displaced from the hole in the center of the limiting aperture substrate 206 so as to be blocked by the limiting aperture substrate 206. On the other hand, when the multiple beams 20a to 20c are not deflected by the common blanking deflector 212, they pass through the hole in the center of the limiting aperture substrate 206 as shown in FIG. 1. Blanking control of all the multiple beams 20 is collectively provided by ON/OFF of the common blanking deflector 212 to collectively control ON/OFF of the beams. Thus, the limiting aperture substrate 206 blocks the multiple beams 20a to 20c which were deflected to be in the OFF condition by the common blanking deflector 212. Then, the multiple beams 20a to 20c for inspection are formed by the beams having been made during a period from becoming “beam ON” to becoming “beam OFF” and having passed through the limiting aperture substrate 206. The multiple beams 20a to 20c having passed through the limiting aperture substrate 206 are adjusted to have a predetermined desired magnification by the magnification adjustment optical system 213. Here, the multiple beams 20a to 20c are adjusted to have a magnification used for defect inspection. Then, the multiple beams 20a to 20c adjusted to have a desired magnification form a crossover (C. O.) by the electromagnetic lens 205 of the magnification adjustment optical system 213. The position of the crossover is adjusted to be the position of the beam separator 214. After passing through the beam separator 214, the multiple beams 20 are focused on the substrate 101 (target object) by the objective lens 207 to be a pattern image (beam diameter) of a desired reduction ratio. All the multiple beams 20 having passed through the limiting aperture substrate 206 are collectively deflected in the same direction by the main deflector 208 and the sub deflector 209 in order to irradiate respective beam irradiation positions on the substrate 101. In such a case, the main deflector 208 collectively deflects all of the multiple beams 20 to the reference position of the mask die which is to be scanned by the multiple beams 20. In the first embodiment, in an inspection mode, scanning is performed while continuously moving the XY stage 105, for example. Therefore, the main deflector 208 performs tracking deflection to further follow the movement of the XY stage 105. Then, the sub deflector 209 collectively deflects all of the multiple beams 20 so that each beam may scan a corresponding region. Ideally, the multiple beams 20 irradiating at a time are aligned at the pitch obtained by multiplying the arrangement pitch of a plurality of holes 22 in the shaping aperture array substrate 203 by a desired reduction ratio (1/a). Thus, the electron beam column 102 irradiates the substrate 101 with two-dimensional m₁×n₁ multiple beams 20 at a time.

A flux of secondary electrons (multiple secondary electron beams 300) (dotted lines in FIG. 1) including reflected electrons, each corresponding to each of the multiple beams 20, is emitted from the substrate 101 due to that desired positions on the substrate 101 are irradiated with the multiple beams 20.

The multiple secondary electron beams 300 emitted from the substrate 101 are refracted toward their center by the objective lens 207, and travel toward the beam separator 214 disposed at the crossover position.

The beam separator 214 generates an electric field and a magnetic field to be orthogonal to each other in a plane orthogonal to the traveling direction (optical axis) of the center beam of the multiple beams 20. The electric field exerts a force in a fixed direction regardless of the traveling direction of electrons. In contrast, the magnetic field exerts a force according to Fleming's left-hand rule. Therefore, depending on the entering direction of an electron, the direction of force acting on the electron can be changed. With respect to the multiple beams 20 (primary electron beams) entering the beam separator 214 from the upper side, since the force due to the electric field and the force due to the magnetic field cancel each other out, the multiple beams 20 go straight downward. On the other hand, with respect to the multiple secondary electron beams 300 entering the beam separator 214 from the lower side, since both the force due to the electric field and the force due to the magnetic field are exerted in the same direction, the multiple secondary electron beams 300 are bent obliquely upward.

While being refracted, the multiple secondary electron beams 300 bent obliquely upward are projected onto the multi-detector 222 by the projection lens 224. The multi-detector 222 detects the projected multiple secondary electron beams 300. The multi-detector 222 may not detect reflected electrons since reflected electrons may diverge in the middle of the optical pass. The multi-detector 222 includes a diode type two-dimensional sensor (not shown), for example. Then, at the position of the diode type two-dimensional sensor corresponding to each of the multiple beams 20, each secondary electron of the multiple secondary electron beams 300 collides with the diode type two-dimensional sensor to produce an electron, and generate secondary electron image data for each pixel. Since scanning is performed while continuously moving the XY stage 105, tracking deflection is provided as described above. Being coincident with the movement of the deflection position along with the tracking deflection, the deflector 228 deflects the multiple secondary electron beams 300 so that they may irradiate respective desired positions on the light receiving surface of the multi-detector 222. The multiple secondary electron beams 300 are detected by the multi-detector 222.

FIGS. 5A and 5B each illustrates a beam size in an inspection mode according to the first embodiment. FIG. 5A shows an example of the beam size of the multiple beams 20 in an inspection mode for defect inspection. In the inspection mode, it is required to detect whether there is a defect 17 on the substrate 101, and its position if the defect 17 exists. Moreover, it is required to reduce the inspection time in order to increase the throughput. Therefore, the beam size of each of the multiple beams 20 is set to be large enough to detect the existence or nonexistence of the defect 17. On the other hand, in an observation usually carried out after detecting the existence of the defect 17 by the defect inspection, an image is required from which even the shape of the detected defect 17 can be discerned. Then, in order to discern the shape of the defect 17, as shown in FIG. 5B, it is necessary to increase the resolution by reducing the beam size. If simply decreasing the magnification of the multiple beams 20 to reduce the beam size, the beam size of each of the multiple beams 20 becomes small, and therefore, simultaneously, the whole size of the multiple beams 20 also becomes small. This means that the pitch between beams of the multiple beams 20 becomes small. If the pitch between beams of the multiple beams 20 changes, the emission position of the multiple secondary electron beams 300 on the substrate 101 also changes, and thus, it becomes difficult to discern which one of the multiple beams 20 corresponds to the secondary electron detected by the multi-detector 222. Therefore, conventionally, when the inspection apparatus detects the defect 17, the shape of the detected defect 17 is observed by using, for example, another SEM (scanning electron microscope) apparatus. Thus, it is inconvenient to relocate the substrate 101 onto another apparatus in order to observe the defect. Then, according to the first embodiment, the mode is divided into an inspection mode and an observation mode. In the inspection mode, defect inspection is performed using the multiple beams 20 whose beam size is relatively large as shown in FIG. 5A. In the observation mode, first, the number of beams is restricted to one such that there is no beam pitch issue, and then, the magnification of the beam is decreased, and an image for observation is acquired by using the beam whose size is relatively small as shown in FIG. 5B. Operations of the image acquisition mechanism 150 in the observation mode are described below.

Similarly to what is described above, for example, a plurality of rectangular electron beams (multiple beams) 20a to 20c (solid lines in FIG. 1) (multiple primary electron beams) are formed by making portions of the electron beam 200 emitted from the electron gun 201 (emission source) individually pass through a corresponding one of the plurality of holes 22 in the shaping aperture array substrate 203.

The formed multiple beams 20a to 20c are refracted toward the hole in the center of the limiting aperture substrate 206 by the electromagnetic lens 218. In other words, when receiving the incident multiple beams, the electromagnetic lens 218 refracts them. Here, the electromagnetic lens 218 refracts the multiple beams 20a to 20c such that the focus position of each beam of them is located at the position of the hole in the center of the limiting aperture substrate 206. Then, while the multiple beams 20a to 20c are passing through the magnetic field of the electromagnetic lens 218, the trajectory corrector 220 (beam selection mechanism) individually corrects the trajectory of each of the multiple beams 20a to 20c, and selects desired (variable) number of beams. Specifically, the trajectory corrector 220 individually corrects the trajectory of each beam by individually apply bias potential or/and deflection potential to each of the multiple beams 20. In the example of FIG. 1, the center beam 20b of the multiple beams 20a to 20c is selected, and trajectories of the other beams 20a and 20c are corrected to be displaced from the hole in the center of the limiting aperture substrate 206. The limiting aperture substrate 206 blocks the beams 20a and 20c which were not selected from the multiple beams 20a to 20c. Thereby, in the observation mode, it is possible to limit the number of the multiple beams 20a to 20c to one beam being desired. For example, the trajectory corrector 220 (beam selection mechanism) selects desired number of beams by individually adjusting focus positions of beams. Specifically, the trajectory corrector 220 individually adjusts focus positions of beams by applying bias potential individually. By shifting the focus position, it is possible to make a target beam collide, on the beam trajectory, with the limiting aperture substrate in order to be blocked. In the inspection mode, the trajectory corrector 220 performs control such that all the beams can pass through the hole in the center of the limiting aperture substrate 206. For example, bias potential or/and deflection potential are not applied. Alternatively, the amount of bias potential or/and deflection potential is controlled so that all the beams can pass through the hole in the center of the limiting aperture substrate 206. Here, since the trajectory corrector 220 individually corrects the beam trajectory, there is no necessity of changing an excitation of the electromagnetic lens 218 between the inspection mode and the observation mode.

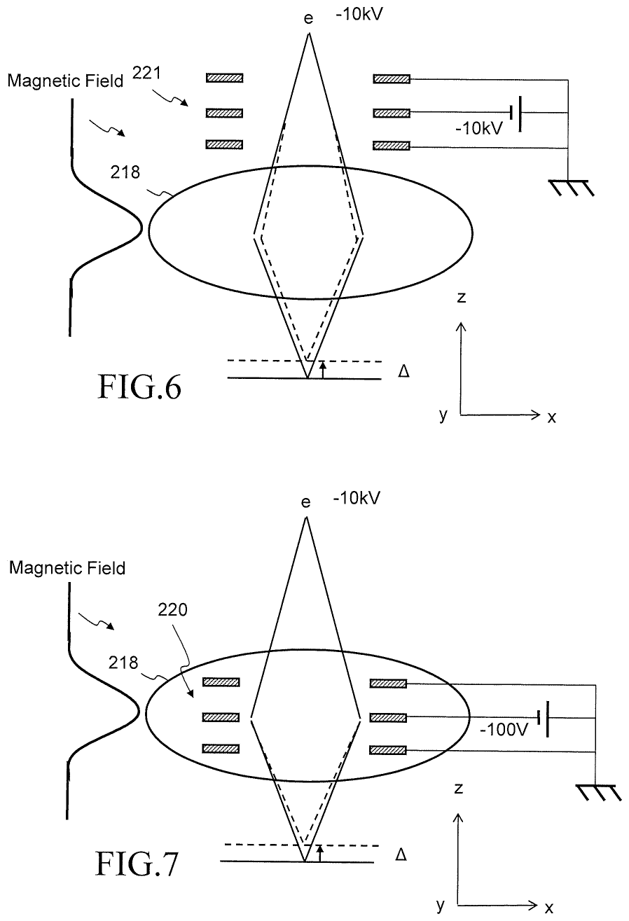

FIG. 6 illustrates trajectory correction of an electron beam by a trajectory corrector according to a comparative example of the first embodiment. In the comparative example of FIG. 6, a trajectory corrector 221 is disposed at the position out of the magnetic field space of the electromagnetic lens 218. FIG. 6 shows the case where the trajectory corrector 221 is configured by three electrode substrates, and the state where the center beam of the multiple beams passes through them. Ground potential is applied to the upper and lower electrode substrates, and negative bias potential is applied to the middle electrode substrate. FIG. 6 omits depiction of the four electrodes on the middle electrode substrate. FIG. 6 shows the case of applying only bias potential. Therefore, the structure of FIG. 6 is similar to that of an electrostatic lens with respect to one beam. In order to change the focus position of the intermediate image focused by the electromagnetic lens 218 with respect to, for example, an electron beam (e) emitted at an acceleration voltage of −10 kV and moving at high speed, bias potential almost equal to the acceleration voltage, such as about −10 kV, is needed. Thus, the voltage to be applied to the trajectory corrector 221 becomes large.

FIG. 7 illustrates trajectory correction of an electron beam by a trajectory corrector according to the first embodiment. In FIG. 7, the trajectory corrector 220 of the first embodiment is disposed in the magnetic field of the electromagnetic lens 218. FIG. 7 shows the state where the center beam of the multiple beams passes through the three electrode substrates of the trajectory corrector 220. FIG. 7 omits depiction of the four electrodes 16 on the middle electrode substrate 12. To facilitate understanding of the description, FIG. 7 shows the case of applying only bias potential. Therefore, the structure of FIG. 7 is similar to that of an electrostatic lens with respect to one beam. Here, for example, if an electron beam (e) emitted at the acceleration voltage of −10 kV and moving at high speed enters the magnetic field of the electromagnetic lens 218, the transfer speed of the electron becomes slow because of the magnetic field. Therefore, when changing the focus position of the intermediate image focused by the electromagnetic lens 218, since the trajectory of an electron beam is corrected by the trajectory corrector 220 in the state where the electron transfer speed is slow, in other words, in the state where the electronic energy is small, it is possible to reduce the bias potential to be applied to the middle electrode substrate to, for example, about −100 V, being 1/100 of the acceleration voltage of −10 kV, for example.

When individually correcting a beam trajectory by the trajectory corrector 220, it is also preferable to individually correct the beam trajectory and to limit the number of beams not only by shifting the focus position of a target beam with using bias potential to be applied to all the four electrodes 16 for each beam also by applying deflection potential so that a potential difference (voltage) may occur between the two opposite electrodes 16a and 16b (or/and 16c and 16d) across the passage hole 13.

The selected beam 20b having passed through the limiting aperture substrate 206 is adjusted to have a predetermined desired magnification by the magnification adjustment optical system 213. Here, the multiple beams 20a to 20c are adjusted to have a magnification used for the observation mode.

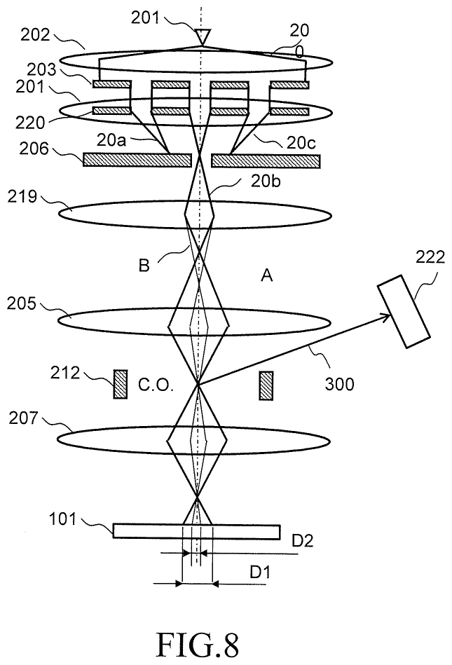

FIG. 8 illustrates magnification adjustment in an observation mode according to the first embodiment. In FIG. 8, as described above, the beams 20a and 20c which were not selected by the trajectory corrector 220 are blocked by the limiting aperture substrate 206. By decreasing the excitation of the electromagnetic lens 219 of the magnification adjustment optical system 213, the refraction index decreases, and therefore, the focus position is moved toward the downstream side (in the direction becoming away from the object surface). Thereby, it is possible to increase the size of the beam 20b at the time of entering the electromagnetic lens 205 by changing the trajectory of the beam 20b from the state of the beam trajectory A to the state of the beam trajectory B. Then, a crossover (C. O.) is formed by the electromagnetic lens 205 of the magnification adjustment optical system 213. The magnification adjustment optical system 213 changes the magnification of a beam so that the crossover position of the beam to irradiate the surface of the substrate 101 maybe a fixed position regardless of the number of selected beams. In other words, the lens control circuit 124 controls the electromagnetic lens 218 in order that the crossover position of the beam 20b selected in the observation mode may not be shifted from the crossover position in the inspection mode. Thereby, the crossover position and the arrangement height position of the beam separator 214 can be the same. Furthermore, it becomes possible to eliminate the need to change the focus position by the objective lens 207 between the inspection mode and the observation mode. After passing through the beam separator 214 disposed at the crossover position, the beam 20b having been adjusted to have a desired magnification is focused on the substrate 101 (target object) by the objctive lens 207 to be a pattern image (beam diameter D2) of a desired reduction ratio to irradiate the substrate 101. In that case, the region to observe can be scanned by deflecting the beam 20b by the main deflector 208 and/or the sub deflector 209.

The secondary electron beam (dotted line in FIG. 1) including a reflected electron is emitted from the substrate 101 due to that a desired position on the substrate 101 is irradiated with the beam 20b. The secondary electron beam emitted from the substrate 101 passes through the objective lens 207, and travels to the beam separator 214 arranged at the crossover position. The secondary electron beam entering the beam separator 214 from the lower side is bent obliquely upward. The secondary electron beam bent obliquely upward is projected onto the multi-detector 222, while being refracted, by the projection lens 224. The multi-detector 222 detects the projected secondary electron beam. Here, since the crossover position has not been changed between the inspection mode and the observation mode, it is not necessary to change the setting of the objective lens 207, the beam separator 214, the projection lens 224, etc. between the inspection mode and the observation mode. Furthermore, since there is only one primary beam, it is not necessary to determine to which beam the secondary electron beam detected by the multi-detector 222 corresponds.

As described above, a signal of the secondary electron beam for image detection can be detected while properly using the beam diameter D1 of each of the multiple beams in the inspection mode and the beam diameter D2 of the beam 20b in the observation mode by selecting a beam(s) by the trajectory corrector 220 disposed in the magnetic field of the electromagnetic lens 218.

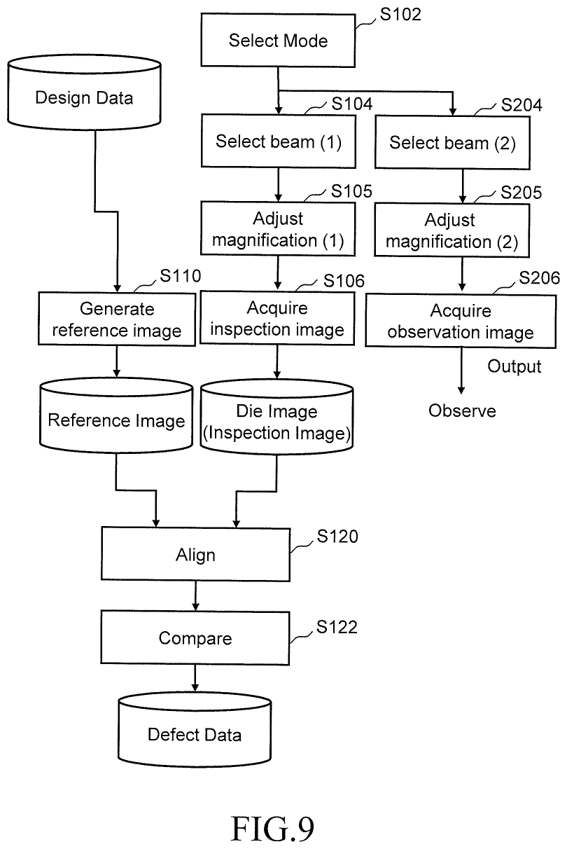

FIG. 9 is a flowchart showing main steps of an inspection method according to the first embodiment. In FIG. 9, the inspection method of the first embodiment executes a series of steps: a mode selection step (S102), a beam selection (1) step (S104), a magnification adjustment (1) step (S105), an inspection image acquisition step (S106), a reference image generating step (S110), an alignment (positioning) step (S120), a comparing step (S122), a beam selection (2) step (S204), a magnification adjustment (2) step (S205), and an observation image acquisition step (S206).

In the mode selection step (S102), the mode selection circuit 132 selects one of the inspection mode (first mode) and the observation mode (second mode), as a mode to be executed (processed). Information on the selected mode is output to the trajectory corrector control circuit 121. When the inspection mode is selected, it proceeds to the beam selection (1) step (S104). When the observation mode is selected, it proceeds to the beam selection (2) step (S204). First, the case of selecting the inspection mode is described below.

In the beam selection (1) step (S104), under the control of the trajectory corrector control circuit 121, a desired number of beams, variable depending on the mode, are selected using the trajectory corrector 220 which is disposed in the magnetic field of the electromagnetic lens 218 for refracting multiple beams and which can individually correct the trajectory of each of the multiple beams. Here, since the inspection mode is selected, the desired number of beams is all the beams. Therefore, the trajectory corrector 220 selects all the multiple beams 20. For example, all the multiple beams 20 are made to pass though the limiting aperture substrate 206 by not performing trajectory correction for each beam. Alternatively, when all the multiple beams 20 do not pass through the hole in the center of the limiting aperture substrate 206 due to aberration and the like of the optical system, it is also preferable to individually correct the trajectory of the beam shifted from the hole in the center of the limiting aperture substrate 206 due to aberration, etc.

In the magnification adjustment (1) step (S105), the magnification adjustment optical system 213 changes the magnification of selected beams, according to the number of beams selected from the multiple beams. As described above, all the beams are selected in the inspection mode. Then, magnification of each beam is adjusted so that the size of each beam may be the size D1 larger compared to that in the observation mode.

In the inspection image acquisition step (S106), the image acquisition mechanism 150 acquires a secondary electron image of a pattern formed on the substrate 101 (target object), using the multiple beams 20. Specifically, it operates as follows:

As described above, the multiple beams 20a to 20c which were selected and whose magnifications have been adjusted pass through the beam separator 214, and are focused on the substrate 101 (target object) by the objective lens 207 in order to irradiate respective beam irradiation positions on the substrate 101 by the main deflector 208 and the sub deflector 209.

A flux of secondary electrons (multiple secondary electron beams 300) (dotted lines in FIG. 1) including reflected electrons, each corresponding to each of the multiple beams 20a to 20c, is emitted from the substrate 101 due to that desired positions on the substrate 101 are irradiated with the multiple beams 20a to 20c. The multiple secondary electron beams 300 emitted from the substrate 101 pass through the objective lens 207 and travel to the beam separator 214 so as to be bent diagonally upward. The multiple secondary electron beams 300 having been bent diagonally upward are projected on the multi-detector 222, while being refracted, by the projection lens 224. Thus, the multi-detector 222 detects the multiple secondary electron beams 300, including reflected electrons, emitted due to that the substrate 101 surface is irradiated with the selected multiple beams 20a to 20c.

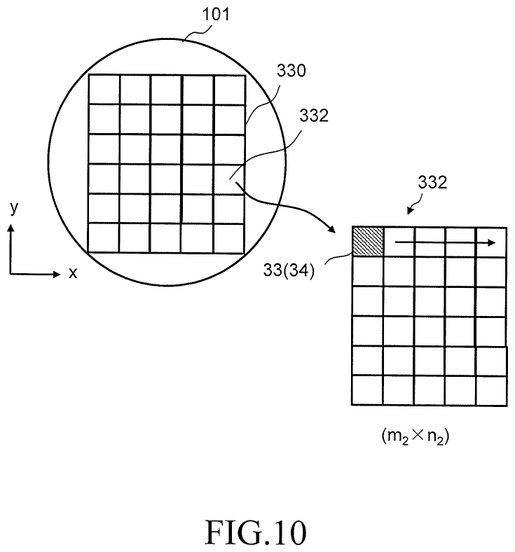

FIG. 10 shows an example of a plurality of chip regions formed on a semiconductor substrate, according to the first embodiment. In FIG. 10, when the substrate 101 is a semiconductor substrate (wafer), a plurality of chips (wafer die) 332 in a two-dimensional array are formed in an inspection region 330 of the semiconductor substrate 101. A mask pattern for one chip formed on the exposure mask substrate has been reduced to ¼, for example, and exposed/transferred onto each chip 332 by an exposure device (stepper) (not shown). The inside of each chip 332 is divided into a plurality of mask dies 33 of m₂ columns wide (width in the x direction) and n₂ rows long (length in the y direction) (each of m₂ and n₂ is an integer of 2 r greater), for example. In the first embodiment, the mask die 33 serves as a unit inspection region.

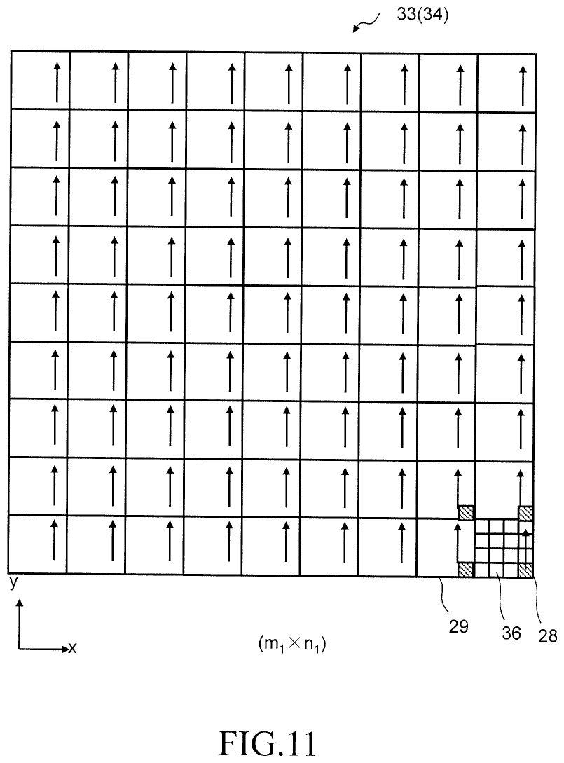

FIG. 11 shows an example of an irradiation region and a measurement pixel of multiple beams according to the first embodiment. In FIG. 11, each mask die 33 is divided into a plurality of mesh regions by the size of each beam of multiple beams, for example. Each mesh region serves as a measurement pixel 36 (unit irradiation region). FIG. 11 illustrates the case of multiple beams of 8×8 (rows by columns). The size of the irradiation region 34 that can be irradiated with one irradiation of the multiple beams 20 is defined by (x direction size obtained by multiplying pitch between beams in the x direction of the multiple beams 20 by the number of beams in the x direction on the substrate 101)×(y direction size obtained by multiplying pitch between beams in the y direction of the multiple beams 20 by the number of beams in the y direction on the substrate 101). In the case of FIG. 11, the irradiation region 34 and the mask die 33 are of the same size. However, it is not limited thereto. The irradiation region 34 may be smaller than the mask die 33, or larger than it. In the irradiation region 34, there are shown a plurality of measurement pixels 28 (irradiation positions of beams of one shot) which can be irradiated with one irradiation of the multiple beams 20. In other words, the pitch between adjacent measurement pixels 28 serves as the pitch between beams of the multiple beams. In the case of FIG. 11, one sub-irradiation region 29 is a square region surrounded at four corners by four adjacent measurement pixels 28, and including one of the four measurement pixels 28. In the example of FIG. 11, each sub-irradiation region 29 is composed of 4×4 pixels 36.

In the scanning operation according to the first embodiment, scanning is performed for each mask die 33. FIG. 11 shows the case of scanning one mask die 33. When all of the multiple beams 20 are used, there are arranged m₁×n₁ sub-irradiation regions 29 in the x and y directions (two-dimensionally) in one irradiation region 34. The XY stage 105 is moved to a position where the first mask die 33 can be irradiated with the multiple beams 20. Then, while the main deflector 208 is performing tracking deflection so as to follow the movement of the XY stage 105, the inside of the mask die 33 concerned being regarded as the irradiation region 34 is scanned in the state of being tracking-deflected. Each beam of the multiple beams 20 is associated with any one of the sub-irradiation regions 29 which are different from each other. At the time of each shot, each beam irradiates one measurement pixel 28 corresponding to the same position in the associated sub-irradiation region 29. In the case of FIG. 11, the main deflector 208 performs deflection such that the first shot of each beam irradiates the first measurement pixel 36 from the right in the bottom row in the sub-irradiation region 29 concerned. Thus, irradiation of the first shot is performed. Then, the main deflector 208 shifts the beam deflection position in the y direction by the amount of one measurement pixel 36 by collectively deflecting all of the multiple beams 20, and the second shot irradiates the first measurement pixel 36 from the right in the second row from the bottom in the sub-irradiation region 29 concerned. Similarly, the third shot irradiates the first measurement pixel 36 from the right in the third row from the bottom in the sub-irradiation region 29 concerned. The fourth shot irradiates the first measurement pixel 36 from the right in the fourth row from the bottom in the sub-irradiation region 29 concerned. Next, the main deflector 208 shifts the beam deflection position to the second measurement pixel 36 from the right in the bottom row by collectively deflecting all of the multiple beams 20. Similarly, the measurement pixels 36 are irradiated in order in the y direction. By repeating this operation, one beam irradiates all the measurement pixels 36 in order in one sub-irradiation region 29. By performing one shot, the multiple secondary electron beams 300 corresponding to a plurality of shots whose maximum number is the same as the number of holes 22 are detected at a time by the multiple beams formed by passing through each of the holes 22 in the shaping aperture array substrate 203.

As described above, all the multiple beams 20 scan the mask die 33 as the irradiation region 34, and that is, each beam individually scans one corresponding sub-irradiation region 29. After scanning one mask die 33, the irradiation region 34 is moved to a next adjacent mask die 33 in order to scan the next adjacent mask die 33. This operation is repeated to proceed scanning of each chip 332. Due to shots of the multiple beams 20, secondary electrons are emitted from the irradiated measurement pixels 36 at each shot time to be detected by the multi-detector 222. In the first embodiment, the size of the unit detection region of the multi-detector 222 is set such that the secondary electron emitted upward from each measurement pixel 36 is detected for each measurement pixel 36 (or each sub-irradiation region 29).

By performing scanning using the multiple beams 20 as described above, the scanning operation (measurement) can be performed at a higher speed than scanning by a single beam. The scanning of each mask die 33 maybe performed by the “step and repeat” operation, alternatively it maybe performed by continuously moving the XY stage 105. When the irradiation region 34 is smaller than the mask die 33, the scanning operation can be performed while moving the irradiation region 34 in the mask die 33 concerned.

When the substrate 101 is an exposure mask substrate, the chip region for one chip formed on the exposure mask substrate is divided into a plurality of stripe regions in a strip form by the size of the mask die 33 described above, for example. Then, for each stripe region, scanning is performed for each mask die 33 in the same way as described above. Since the size of the mask die 33 of the exposure mask substrate is the size before being transferred and exposed, it is four times the mask die 33 of the semiconductor substrate. Therefore, if the irradiation region 34 is smaller than the mask die 33 of the exposure mask substrate, the scanning operation increases by that for one chip (e.g., four times). However, since a pattern for one chip is formed on the exposure mask substrate, the number of times of scanning can be less compared to the case of the semiconductor substrate on which more than four chips are formed.

As described above, using the multiple beams 20, the image acquisition mechanism 150 scans the substrate 101 to be inspected, on which a figure pattern is formed, and detects the multiple secondary electron beams 300 emitted from the inspection substrate 101 due to irradiation of the multiple beams 20 onto the inspection substrate 101. Detection data (measured image: secondary electron image: image to be inspected) on a secondary electron from each measurement pixel 36 detected by the multi-detector 222 is output to the detection circuit 106 in order of measurement. In the detection circuit 106, the detection data in analog form is converted into digital data by an A-D converter (not shown), and stored in the chip pattern memory 123. Thus, the image acquisition mechanism 150 acquires a measured image of a pattern formed on the substrate 101. Then, for example, when the detection data for one chip 332 has been accumulated, the accumulated data is transmitted as chip pattern data to the comparison circuit 108, with information data on each position from the position circuit 107.

In the reference image generating step (S110), the reference image generation circuit 112 (reference image generation unit) generates a reference image corresponding to an inspection image to be inspected. Based on design data serving as a basis for forming a pattern on the substrate 101, or design pattern data defined in exposure image data of a pattern formed on the substrate 101, the reference image generation circuit 112 generates a reference image for each frame region. Preferably, for example, the mask die 33 is used as the frame region. Specifically, it operates as follows: First, design pattern data is read from the storage device 109 through the control computer 110, and each figure pattern defined in the read design pattern data is converted into image data of binary or multiple values.

Here, basics of figures defined by design pattern data are, for example, rectangles and triangles. For example, there is stored figure data defining the shape, size, position, and the like of each pattern figure by using information, such as coordinates (x, y) of the reference position of the figure, lengths of sides of the figure, and a figure code serving as an identifier for identifying the figure type such as a rectangle, a triangle and the like.

When design pattern data, used as the figure data, is input to the reference image generation circuit 112, the data is developed into data of each figure. Then, the figure code, the figure dimensions and the like indicating the figure shape in the data of each figure are interpreted. Then, the reference image generation circuit 112 develops each figure data to design pattern image data of binary or multiple values as a pattern to be arranged in a square in units of grids of predetermined quantization dimensions, and outputs the developed data. In other words, the reference image generation circuit 112 reads design data, calculates an occupancy rate occupied by a figure in the design pattern, for each square region obtained by virtually dividing an inspection region into squares in units of predetermined dimensions, and outputs n-bit occupancy rate data. For example, it is preferable that one square is set as one pixel. Assuming that one pixel has a resolution of ½⁸(= 1/256), the occupancy rate in each pixel is calculated by allocating small regions which correspond to the region of figures arranged in the pixel concerned and each of which corresponds to 1/256 resolution. Then, 8bit occupancy rate data is output to the reference circuit 112. The square region (inspection pixel) should be in accordance with the pixel of measured data.

Next, the reference image generation circuit 112 performs appropriate filter processing on design image data of a design pattern which is image data of a figure. Since optical image data as a measured image is in the state affected by filtering performed by the optical system, in other words, in the analog state continuously changing, it is possible to match/fit the design image data with the measured data by also applying a filtering process to the design image data being image data on the design side whose image intensity (grayscale level) is represented by digital values. The generated image data of a reference image is output to the comparison circuit 108.

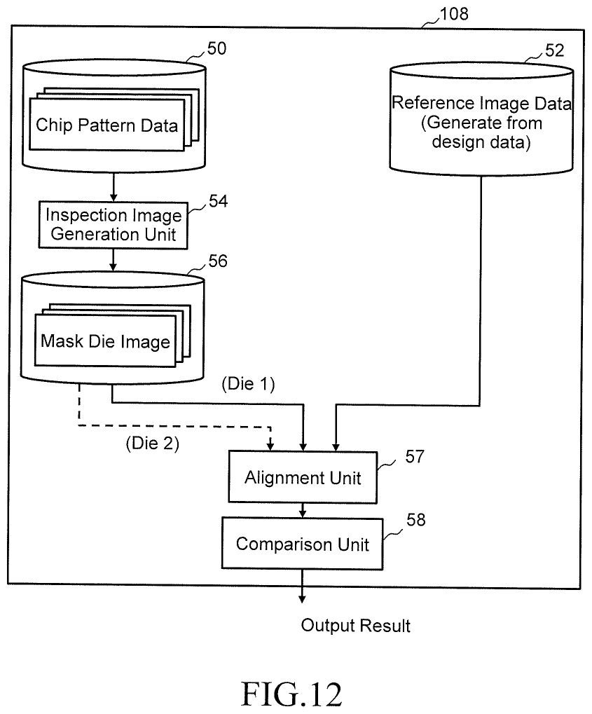

FIG. 12 shows an example of a configuration inside a comparison circuit according to the first embodiment. In FIG. 12, storage devices 50, 52 and 56, such as magnetic disk drives, an inspection image generation unit 54, an alignment unit 57, and a comparison unit 58 are arranged in the comparison circuit 108. Each of the “units” such as the inspection image generation unit 54, the alignment unit 57, and the comparison unit 58 includes processing circuitry. As the processing circuitry, for example, an electric circuit, computer, processor, circuit board, quantum circuit, semiconductor device, or the like can be used. Each of the “units” may use common processing circuitry (same processing circuitry), or different processing circuitries (separate processing circuitries). Input data required in the inspection image generation unit 54, the alignment unit 57, and the comparison unit 58, and calculated results are stored in a memory (not shown) or in the memory 118 each time.

In the comparison circuit 108, transmitted stripe pattern data (or chip pattern data) is temporarily stored in the storage device 50, with information indicating each position from the position circuit 107. Moreover, transmitted reference image data is temporarily stored in the storage device 52.

Next, the inspection image generation unit 54 generates a frame image (inspection image, that is, image to be inspected) by using the stripe pattern data (or chip pattern data), for each frame region (unit inspection region) of a predetermined size. As the frame image, here, an image of the mask die 33 is generated, for example. However, the size of the frame region is not limited thereto. The generated frame image (e.g., mask die image) is stored in the storage device 56.

In the alignment step (S120), the alignment unit 57 reads a wafer die image being an inspection image, and a reference image corresponding to the wafer die image, and provides alignment between the images based on a sub-pixel unit smaller than the pixel 36. For example, the alignment (positioning) may be performed by a least-square method.

In the comparing step (S122), the comparison unit 58 compares the wafer die image (inspection image) and the reference image concerned. The comparison unit 58 compares, for each pixel 36, both the images, based on predetermined determination conditions in order to determine whether there is a defect such as a shape defect. For example, if a grayscale level difference for each pixel 36 is larger than a determination threshold Th, it is determined that there is a defect. Then, the comparison result is output, and specifically, output to the storage device 109, monitor 117, or memory 118, or alternatively, output from the printer 119.

As described above, it is detected whether there is a defect and where the defect exists. Next, the defect is observed.

In the mode selection step (S102), this time, the mode selection circuit 132 selects the observation mode (second mode) as a mode to be executed (processed). Information on the selected mode is output to the trajectory corrector control circuit 121. Now, the case of selecting the observation mode is described below.

In the beam selection (2) step (S204), under the control of the trajectory corrector control circuit 121, a desired number of beams, variable depending on the mode, are selected using the trajectory corrector 220 which is disposed in the magnetic field of the electromagnetic lens 218 for refracting multiple beams and which can individually correct the trajectory of each of the multiple beams. Here, since the observation mode is selected, the desired number of beams is one beam. Therefore, the trajectory corrector 220 selects one beam 20b in the multiple beams 20. For example, trajectories of the other beams other than the center beam 20b are corrected. The limiting aperture substrate 206 blocks the beams 20a and 20c which were not selected from the multiple beams.

In the magnification adjustment (2) step (S205), the magnification adjustment optical system 213 changes the magnification of selected beams, according to the number of beams selected (mode selected) from the multiple beams. As described above, one beam is selected in the observation mode. Then, magnification of the beam is adjusted so that the size of the beam to be used may be the size D2 smaller compared to that in the inspection mode.

In the observation image acquisition step (S206), the image acquisition mechanism 150 acquires a secondary electron image of a pattern formed on the substrate 101 (target object), using the multiple beams 20. Specifically, it operates as follows:

First, the observation position control circuit 130 reads data of a comparison result based on the comparing step (S122) from the storage device 109, and specifies the position which has been determined to be defective, as an observation position. Under the control of the observation position control circuit 130, the image acquisition mechanism 150, first, moves the XY stage 105 to the position where the observation position can be irradiated with the selected beam 20b. Then, the image acquisition mechanism 150 acquires an image of a predetermined size including the observation position. For example, an image of the size of the frame region or of a size smaller than that of the frame region is acquired. When the frame region is the size of 512×512 pixels, for example, an image of the size of 15×15 pixels, for example, centering on the position of the defect is captured as an image for observation.

As described above, the beam 20b whose magnification has been adjusted passes through the beam separator 214, is focused on the substrate 101 (target object) by the objective lens 207 so as to be a pattern image (beam diameter D2) of a desired reduction ratio, and irradiates the substrate 101. In that case, a region to observe is scanned by deflecting the beam 20b by the main deflector 208 and/or the sub deflector 209.

A secondary electron (secondary electron beam) (dotted line in FIG. 1) including a reflected electron, which corresponds to the beam 20b, is emitted from the substrate 101 due to that a desired position on the substrate 101 is irradiated with the beam 20b. The secondary electron beam emitted from the substrate 101 passes through the objective lens 207, travels to the beam separator 214, and is bent obliquely upward. The secondary electron beam bent obliquely upward is projected onto the multi-detector 222 by the projection lens 224. Thus, the multi-detector 222 detects a secondary electron beam, including a reflected electron, emitted from the substrate 101 due to that the substrate 101 is irradiated with the selected beam 20b. Detection data (measured image: secondary electron image: image to be inspected) on a secondary electron detected by the multi-detector 222 is output to the detection circuit 106 in order of measurement. In the detection circuit 106, the detection data in analog form is converted into digital data by an A-D converter (not shown), and stored in the chip pattern memory 123. Thus, the image acquisition mechanism 150 acquires an image for observation, including a defect, formed on the substrate 101.

The acquired image is displayed on the monitor 117, for example. Then, the image displayed on the monitor 117 is observed. Since scanning is performed using a beam of a small size, it is possible to observe an image of high resolution.

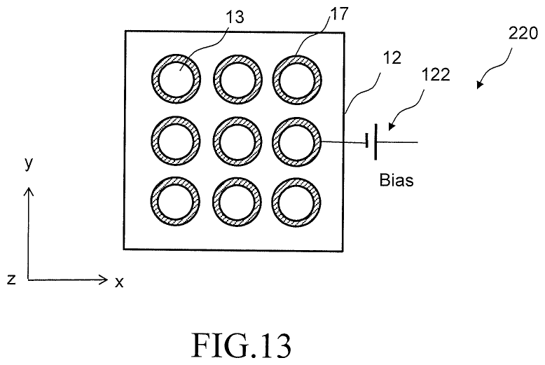

FIG. 13 is a top view showing an example of a middle electrode substrate of a trajectory corrector according to a modified example 1 of the first embodiment. Similarly to the first embodiment, the trajectory corrector 220 is arranged in the magnetic field of the electromagnetic lens 218. The configuration of the upper electrode substrate 10 is the same as that of FIG. 4A. The configuration of the lower electrode substrate 14 is the same as that of FIG. 4C. Then, similarly to the first embodiment, a ground potential (GND) is applied to both the upper and lower electrode substrates 10 and 14 by the trajectory corrector control circuit 121.

On the other hand, with respect to the middle electrode substrate 12 located between the upper and lower electrode substrates 10 and 14, as shown in FIG. 13, an annular electrode 17 is arranged surrounding the passage hole 13 for each of the multiple beams 20. The annular electrode 17 is formed from conductive material. If a bias potential is just individually applied to each beam, it is sufficient to provide the annular electrode 17 instead of the four or more electrodes 16. By individually applying a bias potential to each beam, the focus position of each beam can be corrected individually. Therefore, the beam can be selected according to the mode. Moreover, since the trajectory corrector 220 is disposed in the magnetic field of the electromagnetic lens 218, the bias potential can be reduced as described above.

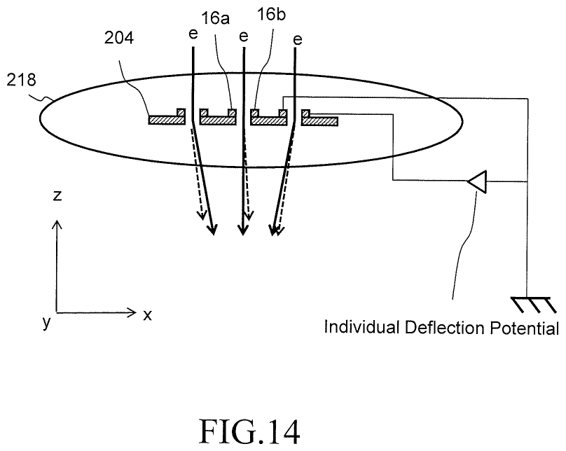

FIG. 14 is a sectional view showing an example of a trajectory corrector according to a modified example 2 of the first embodiment. If not bias potential but deflection potential is applied, the three electrode substrates are unnecessary, and only one substrate is sufficient. In the trajectory corrector 220 of the modified example 2, a plurality of passage holes 13 through each of which a corresponding one of the multiple beams 20 individually passes are formed in the substrate 204, and a plurality of electrode sets, each composed of two or more electrodes 16a and 16b, are disposed on the substrate 204 such that the electrodes 16a and 16b sandwich/surround a corresponding one of the multiple beams 20 passing through the passage holes 13. By performing beam deflection due to a difference between potentials individually applied to the electrodes 16a and 16b in the trajectory corrector 220, the beam can be selected according to the mode.

As described above, according to the first embodiment, it is possible to compatibly perform a defect inspection and a highly accurate observation by the same apparatus when acquiring an image with multiple electron beams.

In the above description, each “. . . circuitry” includes processing circuitry. As the processing circuitry, for example, an electric circuit, computer, processor, circuit board, quantum circuit, semiconductor device, or the like can be used. Each “. . . circuitry” may use common processing circuitry (same processing circuitry), or different processing circuitries (separate processing circuitries). A program for causing a computer to execute the processor and the like may be stored in a recording medium, such as a magnetic disk drive, magnetic tape drive, FD, ROM (Read Only Memory), etc. For example, the position circuit 107, the comparison circuit 108, the reference image generation circuit 112, the observation position control circuit 130, the mode selection circuit 132 and the like may be configured by at least one processing circuitry described above.

Embodiments have been explained referring to specific examples described above. However, the present invention is not limited to these specific examples.

While the apparatus configuration, control method, and the like not directly necessary for explaining the present invention are not described, some or all of them can be selectively used on a case-by-case basis when needed.

In addition, any other multiple electron beam image acquisition apparatus and multiple electron beam image acquisition method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multiple electron beam image acquisition apparatus comprising:
an electromagnetic lens configured to receive incidence of multiple electron beams and refract them;
a beam selection mechanism disposed in a magnetic field of the electromagnetic lens, and configured to be able to individually correct a trajectory of each beam of the multiple electron beams and select a desired number of beams from the multiple electron beams, where the desired number is variable;
a limiting aperture substrate configured to block beams which were not selected from the multiple electron beams;
a magnification adjustment optical system configured to change magnification of the beams selected, depending on a number of the beams, being the desired number, selected from the multiple electron beams;
an objective lens configured to focus the beams selected onto a surface of a target object;
a beam separator configured to separate, from the beams selected, secondary electrons emitted due to that the surface of the target object was irradiated with the beams selected; and
a detector configured to detect the secondary electrons separated by the beam separator.

2. The apparatus according to claim 1, wherein the beam selection mechanism selects the desired number of the beams by individually adjusting focus positions of the beams.

3. The apparatus according to claim 1, wherein the magnification adjustment optical system changes magnification of the beams such that a position of crossover of the beams to irradiate the surface of the target object is a position of the beam separator regardless of the number of the beams selected.

4. The apparatus according to claim 3, wherein the magnification adjustment optical system includes at least two electromagnetic lenses.

5. The apparatus according to claim 1, wherein the objective lens does not change a focus position of the beams selected, in a case of changing the magnification of the beams selected.

6. The apparatus according to claim 1, wherein the beam selection mechanism includes
a plurality of substrates in each of which a plurality of passage holes, through each of which a corresponding one of the multiple electron beams passes, are formed, and
a plurality of electrode sets each composed of two or more electrodes for each of the plurality of passage holes, where the each of the plurality of electrode sets is arranged on one of the plurality of substrates such that the two or more electrodes of the each of the plurality of electrode sets sandwich the corresponding one of the multiple electron beams passing through the plurality of passage holes.

7. The apparatus according to claim 6, wherein a focus position of the each beam of the multiple electron beams is individually adjusted by applying a bias potential, which is set for each of the plurality of passage holes, to the two or more electrodes for the each of the plurality of passage holes.

8. The apparatus according to claim 7, wherein in a case of no trajectory correction being performed by the beam selection mechanism, all of the multiple electron beams pass through the limiting aperture substrate.

9. A multiple electron beam image acquisition method comprising:
selecting, as a mode, one of a first mode and a second mode;
selecting a desired number of beams, where the desired number is variable depending on the mode selected, by a beam selection mechanism disposed in a magnetic field of an electromagnetic lens for refracting multiple electron beams, and configured to be able to individually correct a trajectory of each beam of the multiple electron beams;
blocking beams which were not selected from the multiple electron beams;
changing magnification of the beams selected, depending on the mode selected;
focusing the beams selected onto a surface of a target object; and
acquiring an image of a pattern on the surface of the target object by detecting secondary electrons emitted due to that the surface of the target object was irradiated with the beams selected.

10. The method according to claim 9, wherein the first mode and the second mode have been set in advance as the mode, all of the multiple electron beams are selected in the first mode, and one of the multiple electron beams is selected in the second mode.
